(19) United States
(12) Patent Application Publication
(10) Pub. No.: US 2008/0037309 A1
(43) Pub. Date: Feb. 14, 2008

(54) SEMICONDUCTOR MEMORY DEVICE

(75) Inventor: Tomohito MAKINO, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY INC., Tokyo (JP)

(21) Appl. No.: 11/779,657

(22) Filed: Jul. 18, 2007

(30) Foreign Application Priority Data
Aug. 8, 2006 (JP) 2006-215488

(51) Int. Cl. G11C 5/06

(52) U.S. Cl. 365/63; 365/207

(57) ABSTRACT

Disclosed is a semiconductor memory device in which two sorts of series-connected transfer gates, that is, even-numbered and odd-numbered transfer gates are provided in series with each other between the ends of neighboring bit lines of a memory cell array connecting to bit lines of a sense amplifier. A first bit line of the sense amplifier is connected to a connection node of two, that is, even and odd, transfer gates between two bit lines of the memory cell array. A second bit line of the sense amplifier is connected to a connection node of two, that is, even and odd, transfer gates between two bit lines of the memory cell array. The two sorts of the transfer gates are controlled so that one of bit lines of a bit line pair of the sense amplifier will for all time become the signal side bit line.

### RELATED APPLICATION

This application is based upon and claims the benefit of the priority of Japanese patent application No. 2006-215488, filed on Aug. 8, 2006, the disclosure of which is incorporated herein in its entirety by reference thereto.

### FIELD OF THE INVENTION

This invention relates to a semiconductor memory device. More particularly, this invention relates to a memory device in which connection between a bit line on a sense amplifier and a bit line on a memory cell array may be controlled by a switch.

### BACKGROUND OF THE INVENTION

In the following, a bit line connected to a memory cell which is selected by a word line is referred to as a ‘signal side bit line’ and the bit line which is not the ‘signal side bit line’, that is, a bit line which is to be used as reference during the sense operation, is referred to as a ‘reference side bit line’.

With miniaturization of elements and wires in semiconductor memory devices, demand for low power consumption and increase in operating speed, it is becoming more difficult to design and fabricate sense amplifiers with sufficient symmetry.

FIG. 9 depicts a typical illustrative configuration of a memory cell array section and a sense amplifier section in a typically DRAM (Dynamic Random Access Memory) device. The configuration shown in FIG. 9 is of a folded bit line architecture in which two parallel bit lines connected to a sense amplifier (SA0), such as BL0 and BL1 are connected to the sense amplifier (SA0) in a folded fashion in the same direction. As compared to one-intersection memory cell configuration (open bit line architecture) in which memory cells are arranged at all intersection points of bit lines of a bit line pair (such as BL0 and BL1), and word lines, the folded bit line architecture of FIG. 9 is a two-intersection memory cell configuration in which memory cells are arranged at one-half of intersection points of bit lines of a bit line pair (such as BL0 and BL1), and word lines. This two-intersection memory cell configuration is preferentially used in e.g. large capacity DRAMs because noise between a bit line pair when voltage of a word line changes, for instance, may be expected to be cancelled.

The bit line pairs of a sense amplifier section 2 (such as SA0_BL_TRUE and SA0_BL_BAR), and the bit line pairs of a memory cell array section 1 (such as BL0, BL1), are either coupled directly to each other, as shown in FIG. 9, or associated in a one-for-one relationship via transfer gates, which are not shown but which may be provided at locations surrounded by a dotted line.

In the above configuration, if a word line WL0, for example, is selected, TRUE bit lines of bit line pairs of sense amplifiers SA0 and SA1, that is, TRUE bit line SA0_BL_TRUE and SA1_BL_TRUE, become signal side bit lines (bit lines connected to memory cells MC00 and MC02 which are selected by the word line WL0). In contrast, BAR bit lines (SA0_BL_BAR and SA1_BL_BAR) become reference side bit lines. If a word line WL1 is selected, BAR bit lines of bit line pairs of the sense amplifier (SA0 and SA1), that is, BAR bit line SA0_BL_BAR and SA1_BL_BAR, become signal side bit lines (bit lines connected to memory cells MC11 and MC13 which are selected by the word line WL1). In contrast, TRUE bit lines (SA0_BL_TRUE and SA1_BL_TRUE) become reference side bit lines. The bit line pair (SA0_BL_TRUE and SA0_BL_BAR) of the sense amplifier (SA0) are connected to complementary data input/output lines (IOT and IOB), respectively, via switch transistors, also called ‘Y-switches’, on/off controlled by a column selection signal YS0 from a column decoder, not shown. Likewise, the bit line pair (SA1_BL_TRUE and SA1_BL_BAR) of the sense amplifier (SA1) are connected to the complementary data input/output lines (IOT and IOB), respectively, via switch transistors, also called ‘Y-switches’, on/off controlled by a column selection signal YS1 from a column decoder, not shown.

Meanwhile, there is disclosed in Patent Document 1 the configuration in which bit lines are connected via transfer gates and wiring on both sides of a sense amplifier to the sense amplifier. Two arbitrary bit lines, arranged in symmetrical relation to the sense amplifier, are treated as being in reference position relationship via the wiring. There is also disclosed in Patent Document 2 a configuration of a shared sense amplifier in which transfer gates (Tr1, Tr2) are provided between a bit line (SBL) on the sense amplifier side and a bit line pair (BLL1 and BLL2) on a left side memory array and in which transfer gates (Tr1′ and Tr2′) are provided between a bit line (SBL′) on the sense amplifier side and a bit line pair (BLL1′ and BLL2′) on the memory cell array side. The transfer gates (Tr1, Tr1′) are on/off controlled in common by a signal (SHL1), while the transfer gates (Tr2, Tr2′) are on/off controlled in common by a signal (SHL2). Transfer gates are provided in similar manner between the bit lines on the sense amplifier side and bit line pairs on the right side memory cell array.

### [Patent Document 1]

Japanese Patent Kokai Publication No. JP-A-06-333382

### [Patent Document 2]

Japanese Patent Kokai Publication No. JP-A-09-091952

### SUMMARY OF THE DISCLOSURE

In the configuration of FIG. 9, described above, if the word line WL0 is selected, the bit line (SA0_BL_TRUE) becomes a signal side bit line, while the bit line (SA0_BL_BAR) becomes a reference side bit line. If the word line WL1 is selected, the bit line (SA0_BL_BAR) becomes a signal side bit line, while the bit line (SA0_BL_TRUE) becomes a reference side bit line. That is, which of TRUE and BAR of a bit line pair of a sense amplifier becomes the signal side bit line depends on which of word lines is selected.

It is therefore necessary to design and fabricate a semiconductor memory device so that a sense amplifier will be symmetrical with respect to a bit line pair to ensure an operation speed and the operation margin without regard to which of TRUE and BAR of the bit line pair of the sense amplifier becomes the signal side bit line.

It is also necessary to conduct simulation or tests for operation patterns for 2×2=4 combinations of True and Bar of a bit line pair of the sense amplifier and highs and lows of memory cell data.

Even if a sense amplifier is designed and fabricated symmetrically with respect to a bit line pair, it may exhibit non-symmetry in capacitance and operation.

The non-symmetry in capacitance refers to a signal side bit line connecting to a memory cell of a selected word line being higher in capacitance than a reference side bit line by a value of a memory cell.

The non-symmetry in operation is correlated with the fact that only the signal side bit line pair is required to get to a target potential during refresh and write operations.

However, the configuration, shown in FIG. 9, must be in operation equally regardless of which of True and Bar of a bit line pair of a sense amplifier becomes the signal side bit line. Hence, the sense amplifier must, after all, be designed and manufactured symmetrically with respect to a bit line pair.

It is however becoming increasingly difficult to design and manufacture the sense amplifier with sufficient symmetry with respect to a bit line pair as parasitic components are taken into account.

Accordingly, it is an exemplary object of the present invention to provide a semiconductor memory device in which symmetry with respect to the bit line pair of the sense amplifier does not have to be considered or needs to be considered only to a limited extent. It is another object of the present invention to provide a semiconductor memory device facilitated in designing and manufacture and which is stabilized in operation.

The above and other objects are attained by the present invention summarized substantially as follows:

A semiconductor memory device, in accordance with one aspect of the present invention, comprises a memory cell array including a plurality of memory cells arranged in association with a plurality of word lines and bit lines; and a switching control unit for exercising switching control of connection between a bit line pair of a sense amplifier and associated bit lines of the memory cell array. If a bit line of the memory cell array, connected to a memory cell selected by a word line, is a first bit line as seen from the sense amplifier, the switching control unit connects the first bit line to a first bit line of the bit line pair of the sense amplifier, while connecting a second bit line of the bit line pair of the sense amplifier to a bit line of the memory cell array connected to a non-selected memory cell. If a bit line of the memory cell array, connected to a memory cell selected by a word line, is a second bit line as seen from the sense amplifier, the switching control unit connects the second bit line to the first bit line of the bit line pair of the sense amplifier, while connecting the second bit line of the bit line pair of the sense amplifier to a bit line of the memory cell array connected to a non-selected memory cell.

A semiconductor memory device, in accordance with another aspect of the present invention, comprises a memory cell array including a plurality of memory cells arranged in association with a plurality of word lines and bit lines. The connection between a bit line pair of a sense amplifier and bit lines of the memory cell array relating to the bit line pair is on/off controlled. Three bit lines, namely first to third bit lines, are allocated as bit lines of the memory cell array associated with the sense amplifier. Of these three bit lines, the first bit line or the third bit line or both has switchable connection with a bit line pair of a sense amplifier neighboring to the sense amplifier or with bit line pairs of sense amplifiers on both sides of the sense amplifier. (2n+1) bit lines of the memory cell array are related with (n) of the sense amplifiers, where n is a positive integer. The semiconductor memory device comprises a switching control unit. If the bit line of the memory cell array connected to a memory cell selected by the word line is the first bit line allocated to the bit line pair of the one sense amplifier, the switching control unit connects the first bit line of the memory cell array to a first bit line constituting the bit line pair of said one sense amplifier, while connecting the second bit line of the memory cell array to a second bit line constituting the bit line pair of said one sense amplifier. If the bit line of the memory cell array connected to the memory cell selected by the word line is the second bit line allocated to the bit line pair of the one sense amplifier, the switching control unit connects the second bit line of the memory cell array to the first bit line constituting the bit line pair of the one sense amplifier, while connecting the third bit line of the memory cell array to the second bit line constituting the bit line pair of the one sense amplifier. The bit line of the one sense amplifier connected to the memory cell accessed is the first bit line for all time regardless of which of the word lines is selected.

According to the present invention, the first bit line of the bit line pair of the one sense amplifier is connected to a connection node of two transfer gates connected in series between the ends towards the one sense amplifier of the first bit line and the second bit line of the memory cell array relating to the one sense amplifier. The second bit line of the bit line pair of the one sense amplifier is connected to a connection node of two transfer gates connected in series between the ends towards the one sense amplifier of the second bit line and the third bit line of the memory cell array relating to the one sense amplifier. Even-numbered transfer gates or odd-numbered transfer gates of a transfer gate group are on/off controlled in common by a first control signal, whereas the odd-numbered transfer gates or even-numbered transfer gates are on/off controlled in common by a second control signal.

In still another aspect, the present invention provides a semiconductor memory device in which connection between a bit line pair of a sense amplifier and associated bit lines of a memory cell array is on/off controlled via transfer gates. A first bit line of a bit line pair of one sense amplifier is connected to a connection node of two transfer gates connected in series between the ends towards said sense amplifier of said first bit line and said second bit line of said memory cell array relating to said sense amplifier and a second bit line of said bit line pair of said sense amplifier is connected to a connection node of two transfer gates connected in series between the ends towards said sense amplifier of said second bit line and said third bit line of said memory cell array relating to said sense amplifier, wherein said first bit line and/or said third bit line have switchable connection with a bit line pair of a sense amplifier neighboring to said sense amplifier or with bit line pairs of sense amplifiers on both sides of said sense amplifier. (2n+1) bit lines of said memory cell array are related with n of said sense amplifiers; where n is a positive integer. A set of said transfer gates provided between the ends towards said sense amplifier of the bit lines memory cell array are of first and second sorts. The transfer gates of the first sort are on/off controlled by a first control signal in common and the transfer gates of the second sort are on/off controlled by a second control signal in common.

In still another aspect, the present invention provides a semiconductor memory device in which connection between a bit line pair of a sense amplifier and associated bit lines of a memory cell array is controlled via transfer gates. The semiconductor memory device comprises a switching control unit for exercising switching control between a connection configuration in which first and second bit lines of the bit line pair of the one sense amplifier are connected to even-numbered and odd-numbered bit lines of the memory cell array, relating to the one sense amplifier, respectively, and a connection configuration in which first and second bit lines of the bit line pair of the one sense amplifier are connected to odd-numbered and even-numbered bit lines of the memory cell array relating to the one sense amplifier, respectively. The bit line of the one sense amplifier connected to the memory cell accessed is the first bit line for all time regardless of which of the word lines is selected.

According to the present invention, the first bit line of the bit line pair of the one sense amplifier is connected to a connection node of two neighboring transfer gates between the ends of the first bit line and the second bit line of the memory cell array relating to the one sense amplifier. The second bit line of the bit line pair of the one sense amplifier is connected to a connection node of two neighboring transfer gates between the ends of the second bit line and the third bit line of the memory cell array relating to the one sense amplifier. Out of the transfer gates of the transfer gate group, connected between the ends of the neighboring bit lines of the memory cell array, even-numbered transfer gates are on/off controlled by a first control signal in common, and odd-numbered transfer gates are on/off controlled by a second control signal in common.

According to the present invention, the transfer gates of the transfer gate group are all turned on by the first and second control signals to connect all of the bit lines to carry out the precharging/equalizing operation.

According to the present invention, precharging transistors, on/off controlled by the first and second control signals, are connected to one of the precharging power supply potential and to one of bit lines of the bit line pair of the one sense amplifier.

According to the present invention, there may be provided a logic circuit for generating a precharging control signal that controls the precharging of the bit line pair of the one sense amplifier based on the results of logical operations on the first and second control signals.

According to the present invention, the one sense amplifier is a shared sense amplifier, that is, a sense amplifier shared by memory cell arrays provided on both sides thereof.

According to the present invention, bit lines of the one sense amplifier and bit lines of the memory cell array are arranged alternately and in opposition to each other. One ends of the bit lines of the one sense amplifier towards the memory cell array are extended a preset length in the longitudinal direction beyond the other ends of the bit lines of the memory cell array. The first control signal is arranged as a gate electrode pattern for intersecting the bit lines of the one sense amplifier or the bit lines of the memory cell array. The second control signal is arranged as a gate electrode pattern for intersecting the bit lines of the memory cell array and the bit lines of the one sense amplifier. There are arranged diffusion regions of transfer gates on a surface of a semiconductor substrate on both oblique sides with respect to the longitudinal direction of the gate electrode patterns of the first and second control signals. When one of the diffusion regions on both oblique sides of the gate electrode patterns is connected to the bit lines of the one sense amplifier, the other diffusion region is connected to the bit line of the memory cell array.

In a further aspect, the present invention provides a semiconductor device comprising: a memory cell array including first and second bit lines connected to first and second memory cells as selected by first and second word lines, respectively. The relationship of correspondence in which the case where first and second bit lines of a bit line pair of a sense amplifier provided in association with the first and second memory cells are logic values 1 and 0, respectively, corresponds to a high potential of cell data of the selected memory cell, and the case where the first and second bit lines of the bit line pair of the sense amplifier are of logic values 0 and 1 corresponds to a low potential of cell data of the selected memory cell, is the same insofar as the first and second memory cells are concerned.

In yet another aspect, the present invention provides a semiconductor device including a changeover switch circuit that may be used with advantage as a switch for changing over the destinations of connection of a plural number of signals in unison. The changeover switch circuit comprises:

a first group of signal lines and a second group of signal lines arranged alternately, being spaced apart and in opposition to each other; with the end of said first group of signals being extended beyond the end of said second group of control signals a preset length in the longitudinal direction; a first control signal arranged as a gate electrode pattern for intersecting said first group of signal lines; a second control signal arranged as a gate electrode pattern for intersecting said first and second group of signal lines; and diffusion regions of a transfer gate arranged on each of surface parts of a semiconductor substrate, said diffusion regions lying obliquely on both sides of the longitudinal direction of the gate electrode pattern of each of said first and second control signals. When said diffusion region lying obliquely on one side of said gate electrode patterns is connected to said first signal line, the other diffusion region is connected to said second signal line. Said first signal line is connected to said second signal line, neighboring to said first signal line on one side, when said first control signal is on; and said first signal line is connected to said second signal line, neighboring to said first signal line on the opposite side, when said second control signal is on.

The meritorious effects of the present invention are summarized as follows.

According to the present invention, one of bit lines of a bit line pair of a sense amplifier may for all time be a signal side bit line, by controlling two sorts of the transfer gates. It is therefore only sufficient if the operation is ensured only for the case where one of bit lines of a bit line pair of the sense amplifier is a signal side bit line. Thus, according to the present invention, consideration for symmetry of the sense amplifier may be relaxed or unneeded. According to the present invention, in which consideration for symmetry of the sense amplifier may be relaxed or unneeded, the designing or fabrication margin may be enhanced, making it possible to design a sense amplifier in a manner completely different from the conventional system.

Further, according to the present invention, in which it is only sufficient to ensure the operation for a case where one side bit line of a bit line pair of a sense amplifier becomes a signal side bit line, designing and fabrication margin as well as production yield may be enhanced to make for stabilized operational characteristics. This results because design or adjustment for achieving symmetry with parasitic components taken into account is unneeded even in case of using a sense amplifier that is non-symmetrical with respect to a bit line pair.

Still other features and advantages of the present invention will become readily apparent to those skilled in this art from the following detailed description in conjunction with the accompanying drawings wherein examples of the invention are shown and described, simply by way of illustration of the mode contemplated of carrying out this invention. As will be realized, the invention is capable of other and different examples, and its several details are capable of modifications in various obvious respects, all without departing from the invention. Accordingly, the drawing and description are to be regarded as illustrative in nature, and not as restrictive.

### BRIEF DESCRIPTIONS OF THE DRAWINGS

FIG. 1 is a schematic diagram showing the configuration of an example of the present invention.

FIG. 2 is a schematic diagram showing the configuration of a memory cell of a DRAM of FIG. 1.

FIG. 3 is a schematic diagram showing an example of a sense amplifier of FIG. 1.

FIG. 4 is a timing chart showing an example of the operation of the example of the present invention.

FIG. 5 is a schematic diagram showing the configuration of a second example of the present invention.

FIG. 6 is a diagram showing, in a tabulated form, the relationship of correspondence between the selected word lines and the common gate signals of the second example of the present invention.

FIG. 7 is a schematic diagram showing the configuration of a third example of the present invention.

FIG. 8 is a schematic diagram showing a layout pattern of an example of the present invention.

FIG. 9 is a schematic diagram showing a typical configuration of a sense amplifier and a memory cell array of.

### DETAILED DISCLOSURE OF THE INVENTION

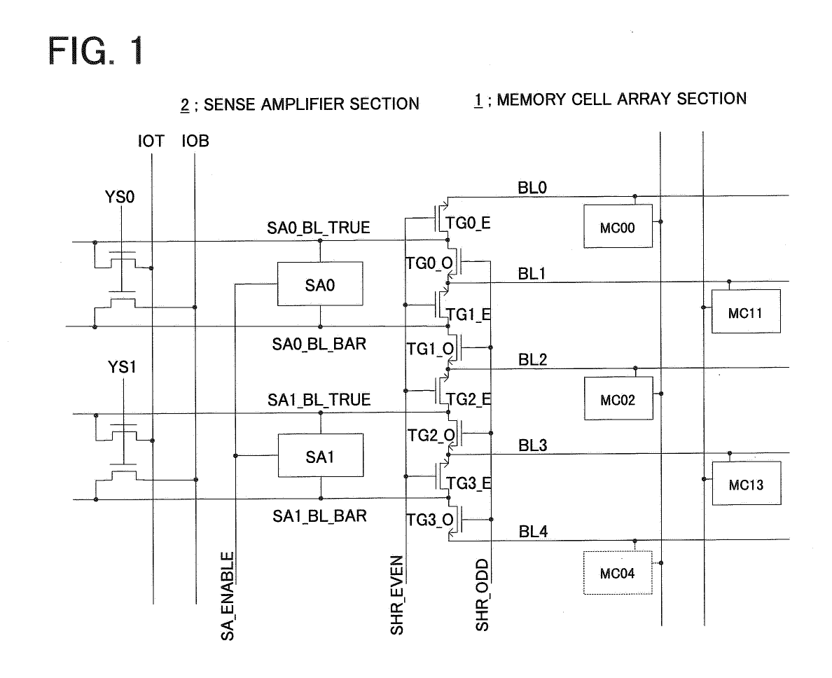

The present invention will be described in further detail with reference to the accompanying drawings. Referring to FIG. 1, in one mode of the present invention, if a bit line of the memory cell array, connected to a memory cell which is selected by a word line (such as WL0), is a first bit line (such as BL0), as seen from the sense amplifier (such as SA0), the first bit line (BL0) is connected to a first bit line (such as SA0_BL_TRUE) of the bit line pair of the sense amplifier, while a second bit line of the bit line pair (such as SA0_BL_BAR) of the bit line pair of the sense amplifier (SA0) is connected to a bit line (BL1) of the memory cell array connected to a non-selected memory cell. If a bit line of the memory cell array, connected to a memory cell which is selected by a word line (such as WL1), is a second bit line (BL1) as seen from the sense amplifier (SA0), the second bit line (BL1) is connected to the first bit line (such as SA0_BL_TRUE) of the bit line pair of the sense amplifier (SA0), while the second bit line (such as SA0_BL_BAR) of the bit line pair of the sense amplifier (SA0) is connected to a bit line (BL2) of the memory cell array connected to the non-selected memory cell.

In more detail, three bit lines, namely first to third bit lines (BL0, BL1, BL2), are allocated as bit lines of the memory cell array relating to one of the sense amplifiers (such as SA0). Of these three bit lines, the third bit line (BL2) may have its connection switched to a bit line (such as SA1_BL_TRUE) of a bit line pair of the sense amplifier (SA1) neighboring to the one sense amplifier (SA0). On the other hand, three bit lines (BL2, BL3, BL4) are allocated as bit lines of the memory cell array relating to a sense amplifier (such as SA1) neighboring to the one sense amplifier (SA0). Of these three bit lines, the first and third bit lines (BL2 and BL4) have their connection switched to one of bit lines of a bit line pair of each of two sense amplifiers (SA0 and SA2, not shown) on both sides of the sense amplifier (SA1).

According to the present invention, (2n+1) bit lines of the memory cell array are related with (n) of the sense amplifiers, where n is a positive integer.

Thus, in one mode according to the present invention, switching control is carried out so that, if a bit line of the memory cell array connected to a memory cell selected by a word line is a first bit line (BL0) allocated to a bit line pair of the one sense amplifier (such as SA0), the first bit line (BL0) is connected to a first bit line (such as SA0_BL_TRUE) constituting the bit line pair of the sense amplifier (SA0), while a second bit line (BL1) is connected to a second bit line (SA0_BL_BAR) constituting the bit line pair of the sense amplifier (SA0). If a bit line of the memory cell array connected to a memory cell selected by the word line is the second bit line (BL1) allocated to the bit line pair of the sense amplifier (SA0), the second bit line (BL1) of the memory cell array is connected to the first bit line (such as SA0_BL_TRUE) constituting the bit line pair of the sense amplifier (SA0), while the third bit line (BL2) of the memory cell array is connected to the second bit line (such as SA0_BL_BAR) constituting the bit line pair of the one sense amplifier (SA0).

To implement this switching control, in an example of the present invention, there are provided two sorts of, that is, even and odd, transfer gates (TG0_E, TG0_O), (TG1_E, TG1_O), (TG2_E, TG2_O) and (TG3_E, TG3_O) connected in series between ends of two neighboring bit lines (BL0, BL1), (BL1, BL2), (BL2, BL3) and (BL3, BL4) of the memory cell array, respectively. The first bit line (such as SA0_BL_TRUE) of a bit line pair of a sense amplifier (such as SA0) is connected to a connection node of two transfer gates, that is, an even transfer gate and an odd transfer gate (TG0_E and TG0_O), connected between the ends of neighboring bit lines (BL0, BL1) of the memory cell array. The second bit line (such as SA0_BL_BAR) of the bit line pair of the sense amplifier (SA0) is connected to a connection node of two transfer gates, that is, an even transfer gate and an odd transfer gate (TG1_E and TG1_O), neighboring to the even and odd transfer gate (TG0_E and TG0_O) to which the first bit line (such as SA0_BL_TRUE) is connected. Out of the even and odd transfer gates, connected between neighboring bit lines of the memory cell array, the first sort of the transfer gates, such as one of the even-numbered transfer gates and the odd-numbered transfer gates (TG0_E, TG1_E, TG2_E and TG3_E), are on/off controlled in common by the first control signal (SHR_EVEN), whereas the second sort of the transfer gates, such as the other of the even-numbered transfer gates and the odd-numbered transfer gates (TG0_O, TG1_O, TG2_O and TG3_O), is on/off controlled in common by the second control signal (SHR_ODD).

According to the present invention, one of the two sorts of the transfer gates is controlled so that one of bit lines of a bit line pair of the sense amplifier will be a signal side bit line for all time.

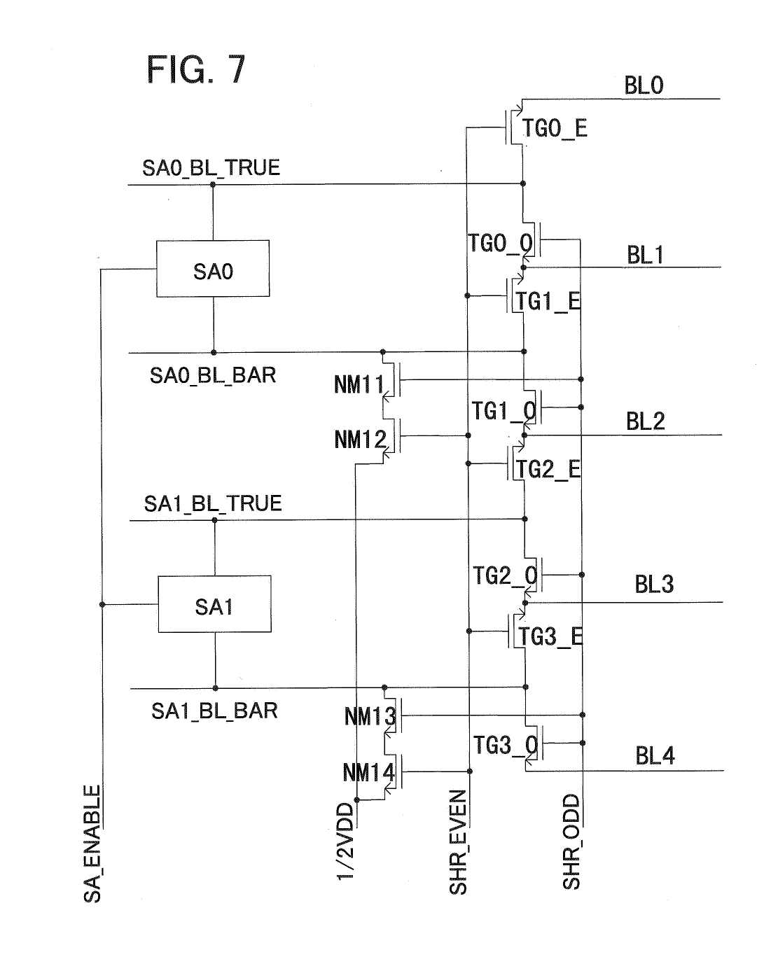

In another mode of the present invention, precharging transistors (NM11, NM12 in FIG. 7), on/off controlled by the first and second control signals, respectively, may be connected between a precharging power supply potential and one of bit lines of a bit line pair of the sense amplifier.

In still another mode of the present invention, there may be provided a logic circuit for generating a precharge control signal that controls the precharging of the bit line pair of the sense amplifier based on the result of logical operation on the first and second control signals supplied to the logic circuit.

The present invention will now be described with reference to its specified example.

FIG. 1 is a diagram schematically showing an example of the present invention. The present example is of a folded bit line type only by way of illustration. Referring to FIG. 1, a memory cell array section 1 includes bit lines (BL0, BL1, BL2, BL3 and BL4) which intersect with word lines (WL0, WL1) in accordance with a two-point intersecting architecture. That is, memory cells MC00, MC02 and MCO4 are arranged at points of intersection of the word line WL0 and the bit lines BL0, BL2 and BL4, whereas memory cells MC11 and MC13 are arranged at points of intersection of the word line WL1 and the bit lines BL1 and BL3.

A sense amplifier section 2 includes, in addition to a plurality of sense amplifiers, the circuitry for precharging bit lines and Y switches which are on/off controlled by column selection signals YS0 and YS1. A TRUE/BAR bit line pair of a sense amplifier SA0, that is, a bit line SA0_BL_TRUE and a bit line SA0_BL_BAR, are connected via Y-switches to a data input/output line pair IOT and IOB. A TRUE/BAR bit line pair of a sense amplifier SA1, that is, a bit line SA1_BL_TRUE and a bit line SA1_BL_BAR, are connected via Y-switches to the data input/output line pair IOT and IOB. A sense amplifier enabling signal SA_ENABLE controls the operation of the sense amplifier.

There are provided transfer gates TG0_E and TG0_O connected in series between bit lines BL0 and BL1 of the memory cell array. The TRUE bit line SA0_BL_TRUE of the sense amplifier SA0 is connected at a connection node of the transfer gates TG0_E and TG0_O.

There are provided transfer gates TG1_E and TG1_O connected in series between bit lines BL1 and BL2 of the memory cell array. The BAR bit line SA0_BL_BAR of the sense amplifier SA0 is connected to a connection node of the transfer gates TG1_E and TG1_O.

There are provided transfer gates TG2_E and TG2_O connected in series between bit lines BL2 and BL3 of the memory cell array. The TRUE bit line SA1_BL_TRUE of the sense amplifier SA1 is connected to a connection node of the transfer gates TG2_E and TG2_O.

There are provided transfer gates TG3_E and TG3_O connected in series between bit lines BL3 and BL4 of the memory cell array. The BAR bit line SA1_BL_BAR of the sense amplifier SA1 is connected to a connection node of the transfer gates TG3_E and TG3_O.

A control signal SHR_EVEN is connected in common to gates of the even transfer gates TG0_E, TG1_E, TG2_E and TG3_E to perform on/off control of these transfer gates in common.

A control signal SHR_ODD is connected in common to gates of the odd transfer gates TG0_O, TG1_O, TG2_O and TG3_O to perform on/off control of these transfer gates in common. Meanwhile, although two sense amplifiers SA0 and SA1, four bit lines BL0 to BL3 of the memory cell array and two word lines (an even word line and an odd word line) WL0 and WL1 are shown in FIG. 1 for simplicity, the present invention is not limited to this configuration.

In FIG. 1, the memory cell MCO4 is arranged at a point of intersection of the bit line BL4 located at an end of the memory cell array and the word line WL0. However, since the bit line BL4, provided at the end of the memory cell array, does not operate as a signal side bit line. Hence, the memory cell MCO4 may not be connected to the bit line BL4, that is, the memory cell MCO4 may be dispensed with. Alternatively, the bit line BL4, provided at the end of the memory cell array, may be a bit line provided as an additional bit line in the memory cell array (dummy bit line). That is, a dummy memory cell MCO4 may be connected to the bit line BL4.

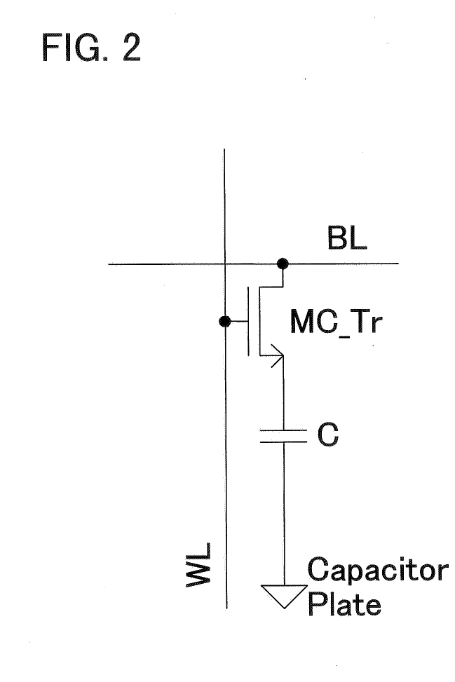

FIG. 2 shows an exemplary configuration of a memory cell of a DRAM. Referring to FIG. 2, the memory cell of the DRAM is made up of one transistor MC_Tr and one capacitor C. The transistor MC_Tr, formed by an NMOS transistor, has a gate connected to a word line WL, has a drain connected to a bit line BL and has a source connected to one end of the capacitor C, the other end of which is connected to a capacitor plate.

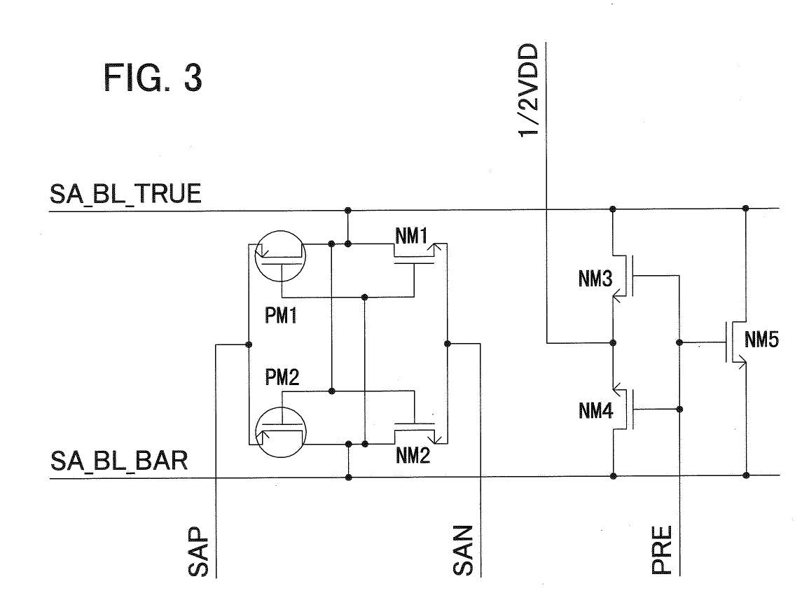

FIG. 3 shows an illustrative configuration of the sense amplifier SA0 or SA1. Referring to FIG. 3, the sense amplifier SA0 or SA1 includes PMOS transistors PM1 and PM2, having sources connected in common to a line SAP, and NMOS transistors NM1 and NM2, having sources connected in common to a line SAN. Drains of the PMOS transistor PM1 and the NMOS transistor NM1 are connected together to a TRUE bit line (non-inverting bit line) SA_BL_TRUE. Drains of the PMOS transistor PM2 and the NMOS transistor NM2 are connected together to a BAR bit line (inverting bit line) SA_BL_BAR. Gates of the PMOS transistor PM1 and the NMOS transistor NM1 are connected together and cross-coupled to a connection node between the drains of the PMOS transistor PM2 and the NMOS transistor NM2. Gates of the PMOS transistor PM2 and the NMOS transistor NM2 are connected together and cross-coupled to a connection node between the drains of the PMOS transistor PM1 and the NMOS transistor NM1. The sense amplifier SA0 or SA1 also includes NMOS transistors NM3 and NM4, having sources connected to bit lines SA_BL_TRUE and SA_BL_BAR, having drains connected together to a precharge power supply (½VDD) and having gates supplied with a precharge signal PRE. The sense amplifier SA0 or SA1 further includes an NMOS transistor NM5, connected between the bit lines SA_BL_TRUE and SA_BL_BAR and having a gate supplied with the precharge signal PRE. The NMOS transistors NM3 and NM4 make up a precharge circuit and the NMOS transistor NM5 makes up an equalizer circuit. It should be noted that the precharge equalizer circuit, made up of the NMOS transistors NM3, NM4 and NM5, may be provided, instead of between the paired bit lines of the sense amplifier, such as the sense amplifier SA0, but between bit lines BL0 and BL1 on the side of the memory cell array section 1 with respect to the transfer gates (TG0_E and TG0_O).

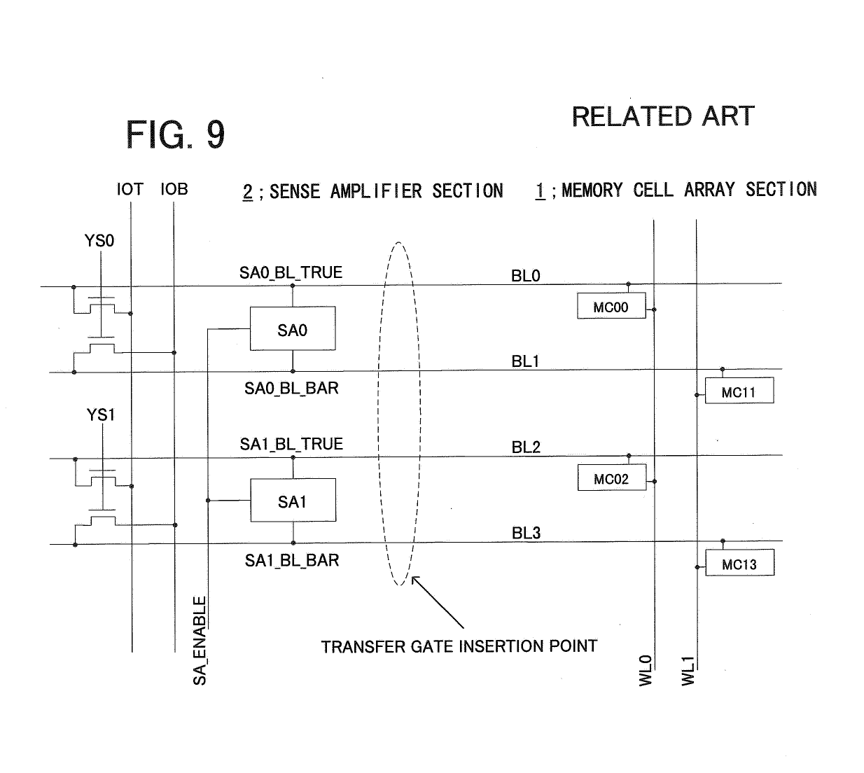

In case the configuration shown in FIG. 3 is applied to the sense amplifier of FIG. 9, it is necessary that the resulting sense amplifier configuration is symmetrical with respect to the bit line pair SA_BL_TRUE and SA_BL_BAR.

In contrast, if the configuration shown in FIG. 3 is applied to the sense amplifier shown in FIG. 1, the resulting sense amplifier configuration may be non-symmetrical with respect to the bit line pair. For example, the current driving performance (gain coefficient β, that is proportionate to W/L ratio) of the PMOS transistor PM1 of FIG. 3 may be made higher than that of the PMOS transistor PM2, while the current driving performance (gain coefficient β, that is proportionate to W/L ratio) of the NMOS transistor NM2 may be made higher than that of the NMOS transistor NM1. By so doing, it becomes possible to speed up the pull-up of the TRUE side to the high potential (SAP potential) and the pull-down of the BAR side to the low potential (SAN potential) by the sense amplifier flip-flop.

The operation of the DRAM circuit of the present example is now described. The voltages used (power supply voltage) are two voltage stages (High and Low) and a voltage intermediate the two voltages, or ½VDD (precharge voltage).

It is assumed that, in FIG. 1, the High voltage is written as cell data in the memory cells MC00 and MC11, while the Low voltage is written as cell data in the memory cells MC02 and MC13.

The sequence of operations for exercising control so that the signal side bit line and the reference side bit line become the TRUE bit line and the BAR bit line of the sense amplifier, respectively, is now described.

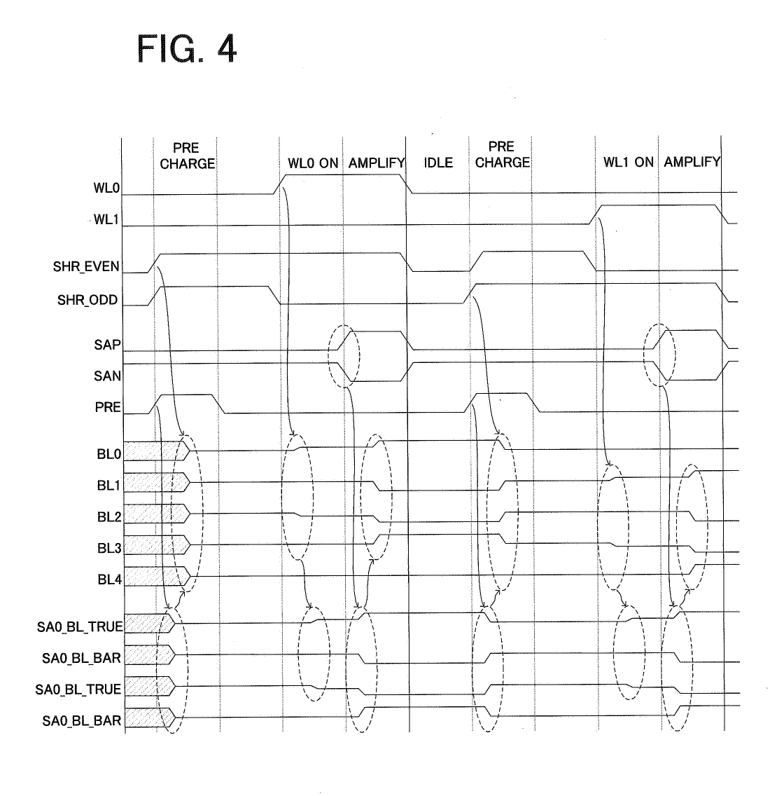

FIG. 4 depicts a timing chart for explaining this control sequence of the present example.

The case of reading a signal from a memory cell connected to a word line WL0, as an exemplary case of selecting an even word line, will be described.

If the bit lines BL0 and BL2, out of the bit lines BL0, BL2 and BL4, connected respectively to the memory cells MC00, MC02 and MC04, in turn connected in common to the selected word line WL0, are connected to the TRUE bit lines SA0_BL_TRUE and SA1_BL_TRUE of the sense amplifiers SA0 and SA1, respectively, it is sufficient to set the control signals SHR_EVEN and SHR_ODD to High and Low, respectively.

Initially, the precharge control signal PRE and SHR_EVEN are set to High to effect bit line equalizing/precharging (see ‘PRECHARGE’ in FIG. 4). The control signal SHR_ODD may also be set to High at this time, as shown in FIG. 4. With the control signals SHR_EVEN and SHR_ODD becoming High during the pre-charge period, the transfer gates TG0_E, TG1_E, TG2_E, TG3_E, TG0_O, TG1_O, TG2_O and TG3_O are all ON. The bit line pairs (SA0_BL_TRUE, SA0_BL_BAR, SA1_BL_TRUE and SA1_BL_BAR) of the sense amplifiers and all bit lines (BL0, BL1, BL2, BL3 and BL4) of the memory cell array are rendered current conductive and are equalized/precharged to ½VDD.

When the equalizing/precharging has come to a close, the precharge control signal PRE and the control signal SHR_ODD are set to Low. The control signal SHR_EVEN is kept at a High level.

The word line WL0 is then set to High (see ‘WL0 ON’ of FIG. 4). The sense amplifiers SA0 and SA1 read signal voltages of the memory cells MC00 and MC02 (voltages on the bit lines BL0 and BL2), respectively. In this case, the signal paths of cell data are from BL0 to SA0_BL_TRUE and from BL2 to SA1_BL_TRUE.

The signals SAN and SAP, controlling the activation of the sense amplifier, are set to a Low potential and to a High potential, respectively, to activate the sense amplifiers SA0 and SA1 to amplify the voltage on the bit line pairs (see ‘AMPLIFY’ of FIG. 4). The sense amplifiers SA0 and SA1 are each constituted by a flip-flop composed of two inverters, having inputs and outputs cross-coupled to each other. The sense amplifiers each amplify the bit line pair voltage with the TRUE and BAR bit lines of the bit line pairs as a signal side bit line and as a reference side bit line, respectively.

When the voltage has been amplified by the sense amplifier, the word line WL0 is set to Low, whilst the signals SAN and SAP are set to High and Low, respectively (see ‘IDLE’ of FIG. 4).

In the example of FIG. 4, SHR_EVEN is set from High to Low during the IDLE period. However, considering that SHR_EVEN is set to High during the next following precharge period, it is not essential to set SHR_EVEN to Low during the IDLE period. That is, SHR_EVEN may be kept to be High during the IDLE period and the next following PRECHARGE period.

Referring to FIGS. 1 and 4, the case of reading a signal from a memory cell connected to the word line WL1 is described.

In order to connect the bit lines BL1 and BL3, to which are connected the memory cells MC1 and MC13 connected in common to a selected word line WL1, to the bit lines SA0_BL_TRUE and SA1_BL_TRUE on the sense amplifier side, it is sufficient to set SHR_EVEN and SHR_ODD to Low and high, respectively.

Bit line equalizing/precharging is carried out with both the precharge control signal PRE and the control signal SHR_ODD set to High (see ‘PRECHARGE’ next to ‘IDLE’ of FIG. 4). In the example shown in FIG. 4, not only SHR_ODD but SHR_EVEN is set to High. The bit lines of the sense amplifier and all bit lines BL0 to BL4 of the memory cell array are equalized/precharged to ½VDD. When the equalizing/precharge has come to a close, both the precharge control signal PRE and the control signal SHR_EVEN are set to Low.

The word line WL1 is then set to High (see ‘WL1 ON’ of FIG. 4). The sense amplifiers SA0 and SA1 read the signal voltages of the cell data of the memory cells MC11 and MC13 (voltages on the bit lines BL1 and BL3). The signal paths of the cell data are from BL1 to SA0_BL_TRUE and from BL3 to SA1_BL_TRUE.

The signals SAN and SAP are set to High to activate the sense amplifiers SA0 and SA1 to amplify the bit line voltages (see ‘AMPLIFY’ next to ‘WL1 ON’ of FIG. 4).

When the bit line voltages have been amplified by the sense amplifiers SA0 and SA1, the word line WL1 is set from High to Low, and the signal SAN is set to High, while the signal SAP is set to Low (IDLE not shown in FIG. 4).

In the above two operations, which of the bit lines of the memory cell array section 1 becomes the signal side bit line or the reference side bit line depends on the particular word line selected. However, by controlling the values of the control signals SHR_EVEN and SHR_ODD, the TRUE bit line and the BAR bit line necessarily become the signal side bit line and the reference side bit line, on the sense amplifier side, respectively.

Meanwhile, in designing and manufacturing a sense amplifier for a DRAM, a memory cell with a single transistor, it is crucial how quickly a sufficient High level is written in each cell.

That is, the degree of importance in the various steps of the amplifying operation by the sense amplifier falls in the following sequence:

(1) the step of setting the signal side bit line to High;
(2) the step of setting the reference side bit line to Low;
(3) the step of setting the signal side bit line to Low; and
(4) the step of setting the reference side bit line to High.

Preferably, the sense amplifier is designed so as to be good at the crucial step of the amplifying operation.

In the configuration, shown in FIG. 9, which of bit lines of the bit line pair of the sense amplifier is to be a signal side bit line is changed over in dependence upon the selected word line. It is therefore necessary to design and fabricate the sense amplifier symmetrically with respect to the bit line pair.

In contrast, in the present example, control may be exercised so that only one of bit lines of a bit line pair of the sense amplifier will become the signal side bit line at all times. This yields the following meritorious operation and result.

(A) The design of circuit and layout of the semiconductor memory device may be facilitated. According to the present invention, it is sufficient that correct operations take place only if one of bit lines of a bit line pair becomes the signal side bit line, even though symmetry in operation characteristics collapsed due to parasitic components (parasitic capacitance or resistance) or non-symmetrical designing is used on purpose. This results in designing with sufficient allowance in the operation speed and margin as compared to the conventional configuration, thus making for improved reliability in the stability of operational characteristics.
(B) The fabrication of semiconductor memory devices may be facilitated with improvement in yield. It is sufficient that, even if characteristics are deviated due to variations in fabrication, the correct operations take place only in case one of the bit lines of the bit line pair becomes the signal side bit line. This results in improved allowance as compared to the conventional configuration.
(C) The simulation for a sense amplifier may be simplified. In the configuration of FIG. 9, it is necessary to carry out the simulation for 2×2=4 operational patterns for True and Bar of the bit lines and High and Low of the memory cell. In the configuration of the present invention, it is sufficient to carry out the simulation for two operation patterns, namely High and Low of the memory cell. However, it is necessary to carryout separate simulation for the transfer gates and the control circuit therefor.

In the configuration of FIG. 9, if, in formulating test patterns, a High potential is written from the sense amplifier SA0 in the memory cell MC00, selected by the word line WL0, it is necessary to set write data so that IOT=High (IOB=Low). If a High potential is written from the sense amplifier SA0 in the memory cell MC1, selected by the word line WL1, it is necessary to set write data so that IOT=Low (IOB=High). Thus, if a high potential is written in a memory cell, in conducting a memory test, it is necessary to change over the logic values of the write data, that is, the logic values to be given the data input/output line pair IOT and IOB, for the memory cell connected to the bit line pair, depending on the selected word line.

In contrast, in the present example, shown in FIG. 1, in case a High potential is written from the sense amplifier SA0 in the memory cell MC00, selected by the word line WL0, it is sufficient to set IOT=High (IOB=Low) as write data. In case a High potential is written from the sense amplifier SA0 in the memory cell MC11, selected by the word line WL1, it is sufficient to set IOT=High (IOB=Low) as write data. That is, High data of the memory cells MC00 and MC11, connected to the bit line pair, relate to the High potential of the TRUE bit line of the sense amplifier and the data input/output line IOT, whilst the Low data of the memory cells MC00 and MC11 relate to the Low potential of the TRUE bit line of the sense amplifier and the data input/output line IOT. The same applies for read operation. With the present example, the potential of cell data of the memory cell connected to the bit line pair is in one-for-one correspondence with the logic value of the data input/output line, regardless of the word line selection, thus making it possible to prepare test patterns with ease. It is also possible to prepare patterns with ease by BIST (Built In Self Test) embedded on a semiconductor memory device which has a semiconductor memory.

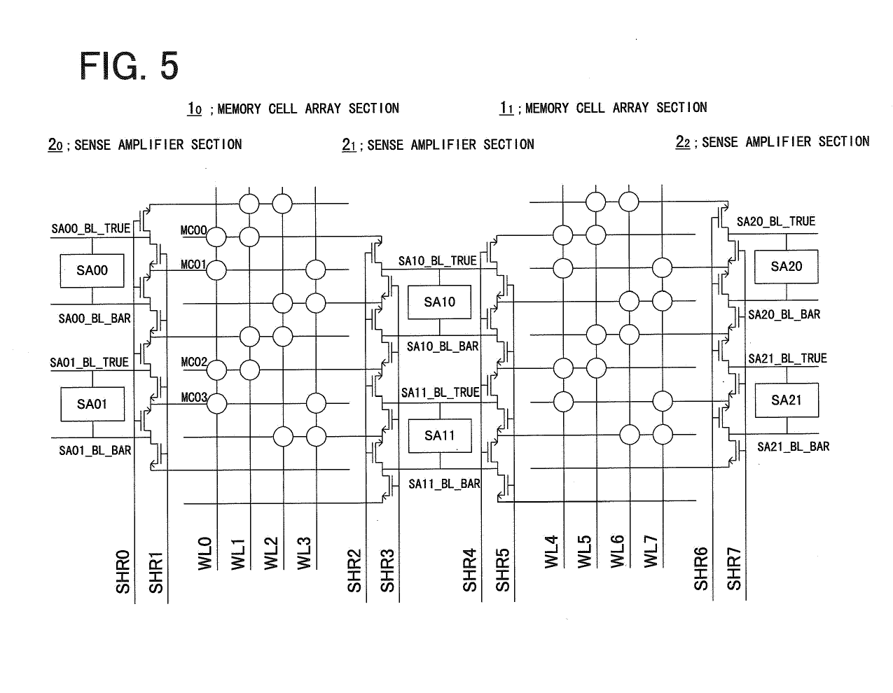

A second example of the present invention is now described. FIG. 5 is a diagram schematically showing the second example of the present invention. The present example is an example of application to a DRAM that uses a bit map of folded bit line type, sense amplifiers arranged on both sides of memory cell arrays, bit line division and a shared sense amplifier configuration. Memory cells are arranged at points of intersections of word and bit lines indicated by circles. The example of FIG. 5 uses control signals SHR0 and SHR1 for controlling the connection by transfer gates between bit line pairs of sense amplifiers (SA00 and SA01) of a sense amplifier section 2₀ and mating bit lines of the memory cell array section 1₀. The example of FIG. 5 also uses control signals SHR2 and SHR3 and control signals SHR4 and SHR5 for controlling the connection by transfer gates between bit line pairs of sense amplifiers (SA10 and SA11) of a sense amplifier section 2₁ and mating bit lines of the memory cell array section 1₀ and the memory cell array section 1₁. The example of FIG. 5 also uses control signals SHR6 and SHR7 for controlling the connection by transfer gates between bit line pairs of sense amplifiers (SA20 and SA21) of a sense amplifier section 2₂ and mating bit lines of the memory cell array section 1₁.

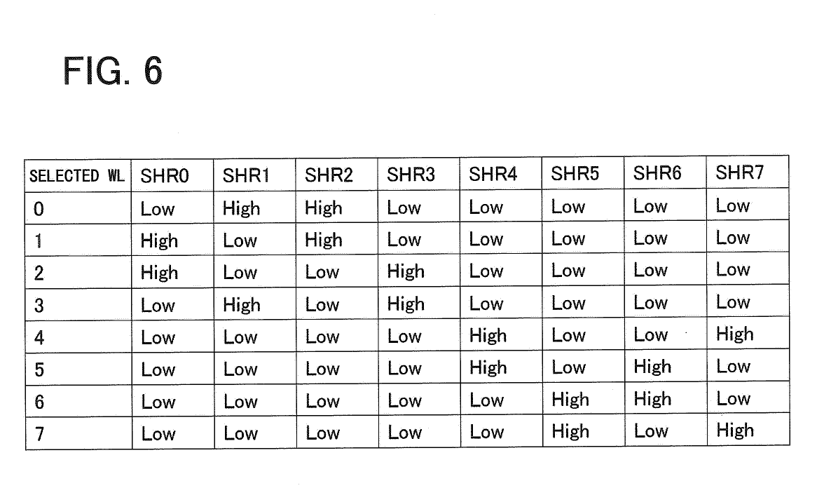

If a TRUE bit line (SAxx_BL_TRUE) of each sense amplifier of each of the sense amplifier sections 2₀, 2₁ and 2₂ is connected to the bit line connected to the memory cell selected by the word line, the relationship between the word lines WL0 to WL7 and the controlled signals SHR0 to SHR7 is as shown in FIG. 6. It is noted that FIG. 6 shows a list of word lines selected and control of activation of the control signals SHR1 to SHR7 that on/off control transfer gates in the configuration of FIG. 5.

With the control of FIG. 6, the TRUE bit lines and the BAR bit lines of the sense amplifiers at all times become signal side lines and reference side bit lines, respectively. Taking a more specific example, if the word line WL0, for example, is selected, the control signals SHR1 and SHR2 are set to High, whereas the remaining control signals SHR0 and SHR3 to SHR7 are set to Low. The data of the memory cell MC00, connected to the selected word line WL0, is supplied via transfer gate to the TRUE bit line SA10_BL_TRUE of the sense amplifier SA10. The data of the memory cell MC01 is supplied via transfer gate to the TRUE bit line SA00_BL_TRUE of the sense amplifier SA00. The data of the memory cell MC02 is supplied via transfer gate to the TRUE bit line SA11_BL_TRUE of the sense amplifier SA11. The data of the memory cell MC03 is supplied via transfer gate to the TRUE bit line SA01_BL_TRUE of the sense amplifier SA01.

In the present example, the transfer gate is used simultaneously as a transfer gate for a shared amplifier, and hence the increase in the chip area as compared to that of the conventional shared amplifier system is negligible.

A third example of the present invention is now described. FIG. 7 shows the configuration of the third example of the present invention. The present example includes, in addition to the configuration of the previous example of FIG. 1, a set of NMOS transistors NM11 and NM12, and another set of NMOS transistors NM13 and NM14. The NMOS transistors NM11 and NM12 have gates connected to the lines SHR_ODD and SHR_EVEN, respectively, and are connected between the BAR bit line SA0_BL_BAR of the sense amplifier SA0 and a ½VDD (precharge power supply). The NMOS transistors NM13 and NM14 have gates connected to the lines SHR_ODD and SHR_EVEN, respectively, and are connected between the BAR bit line SA1_BL_BAR of the sense amplifier SA1 and the ½VDD (precharge power supply).

In the present example, both the control signals SHR_EVEN and SHR_ODD of the transfer gates are set to High, during the precharge period, as shown in FIG. 4. This connects together, that is, equalizes, all of the bit lines (bit line pairs SA0_BL_TRUE, SA0_BL_BAR, SA1_BL_TRUE and SA1_BL_BAR of the sense amplifiers and bit lines BL1 to BL4 of the memory cell array), so that the bit lines are supplied with the precharge voltage ½VDD. Meanwhile, in the example of FIG. 7, the NMOS transistors NM11 and NM13 are connected to the BAR bit lines of the sense amplifiers SA0 and SA1, in consideration of the capacitances of the non-selected cells. The BAR bit lines of the sense amplifiers SA0 and SA1 are reference side bit lines at all times.

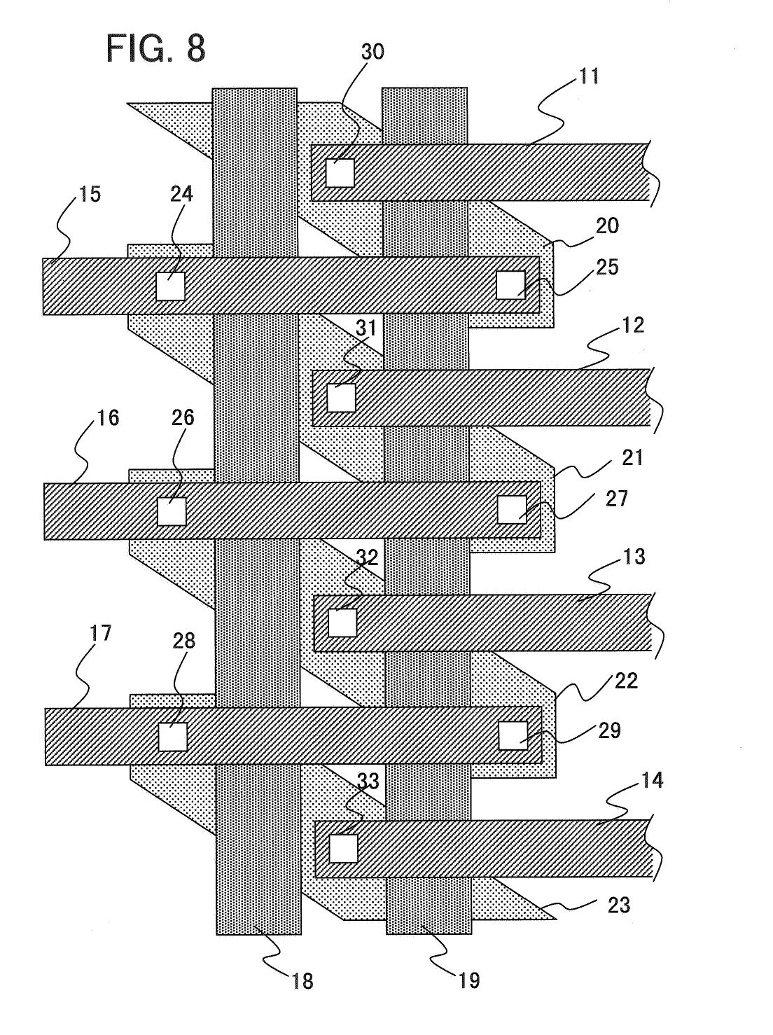

An illustrative layout is now described as another example of the present example. FIG. 8 shows an illustrative layout for transfer gates and bit lines of the memory cell array. In FIG. 8, lines 11 to 14 and 15 to 17, extending in the left and right direction, denote bit lines. In FIG. 8, lines 18 and 19, extending in the up-and-down direction, denote common gate lines of the transfer gates, that is, gate electrode wires, indicated by SHR_EVEN and SHR_ODD of FIG. 1. Moreover, in FIG. 8, oblique regions 20 to 23 denote diffusion regions (highly doped impurity regions) of the transfer gates, and regions 24 to 33 denote contacts.

The bit lines (15 to 17) on the sense amplifier side and the bit lines (11 to 14) on the memory cell array side are opposed and arranged alternately. The ends of the bit lines (15 to 17) on the sense amplifier side are extended a preset length beyond the ends of the bit lines (11 to 14) of the sense amplifier side in the longitudinal direction. That is, the ends of the bit lines (15 to 17) overlap with the ends of the bit lines (11 to 14). A first control signal is arranged as a gate electrode pattern (18) for crossing the bit lines (15 to 17) on the sense amplifier side. A second control signal is arranged as a gate electrode pattern (19) in an overlapping area of the bit lines (15, 16, 17) on the sense amplifier side and the bit lines (11 to 14) on the memory cell array side. Diffusion layers (20 to 23) of the transfer gates are arranged on a substrate surface laid out obliquely on both sides of the longitudinal direction of the gate electrode patterns (18, 19) of the first and second control signals. The diffusion regions lying obliquely on both sides of the gate electrode patterns may be configured so that, when one of the diffusion regions is connected to the bit lines of the sense amplifiers, the other diffusion region is connected to the bit lines of the memory cell array.

The layout is now described in more detail with reference to FIG. 8. The bit lines 15 to 17, connected to contacts 24, 25, 26, 27, 28 and 29 at the ends of the diffusion regions 20 to 23, are bit lines of the sense amplifier, that is, bit lines SA0_BL_TRUE, SA0_BL_BAR, SA1_BL_TRUE, . . . . The bit lines 11 to 14, connected to center contacts 30 to 33 of the diffusion regions 20 to 23, are bit lines of the memory cell array (bit lines BL0, BL1, BL2 and BL3). The above applies for the case where the left side of FIG. 8 is the sense amplifier side. Conversely, for a case where the right side of FIG. 8 is the sense amplifier side, the layout may be such that bit lines 15 to 17, connected to the contacts 24, 25, 26, 27, 28 and 29 at the ends of the diffusion regions 20 to 23, are bit lines of the memory cell array, and the bit lines 11 to 14, connected to the center contacts 30 to 33, are bit lines of the sense amplifier.

It is assumed that the diffusion regions 20 to 23 are n⁺ diffusion regions, and the transfer gate is an NMOS transistor. It is also assumed that the gate electrodes 18, 19 are at a High potential and at a Low potential, respectively. The bit lines 15 to 17 are electrically connected from the contacts 24, 26 and 28 through a region directly below the gate electrode 18 and through the contacts 30 to 32 to the bit lines 12, 13 and 14, respectively. If the gate electrodes 18, 19 are at a Low potential and at a High potential, respectively, the bit lines 15 to 17 are electrically connected from the contacts 25, 27 and 29 through a region directly below the gate electrode 18 and through the contacts 30 to 32 to the bit lines 11, 12 and 13, respectively. It should be noted that a switch where the diffusion regions and the channels are arranged obliquely with respect to the gate electrodes and connection between n signal lines and (n+1) signal lines is changed over every n signal lines, is not limited to a transfer gate that on/off controls the connection of the bit lines of the memory cell array and those of the sense amplifier, and may be any desired type of the changeover switch.

In the present example, in case common gates of the odd and even transfer gates are both rendered current conductive to connect all of the bit lines together to carry out the equalizing and precharge operation, it is possible to dispense with the separate precharge control signal line PRE from the decoder to the sense amplifier. In such case, the precharge control signal line PRE may be used in common with the common gate signal lines to generate the control signal PRE in the vicinity of the sense amplifier with use of e.g. an AND gate. If the transfer gate and the precharge MOS transistor are both NMOS transistors, an output of the AND circuit, supplied with the common gate signals SHR_EVEN and SHR_ODD of the even and odd transistors, becomes a precharge control signal. That is, in FIG. 7, the AND circuit, not shown, supplied with the common gate signals SHR_EVEN and SHR_ODD, is used to generate the control signal PRE (see FIG. 3).

If the transfer gate and the precharge MOS transistor are both PMOS transistors, an OR of the common gate signals SHR_EVEN and SHR_ODD becomes a precharge control signal. If the transfer gate is an NMOS transistor and the precharge MOS transistor is a PMOS transistor, a NAND of the common gate signals SHR_EVEN and SHR_ODD becomes a precharge control signal. If the transfer gate is a PMOS transistor and the precharge MOS transistor is an NMOS transistor, a NOR of the common gate signals SHR_EVEN and SHR_ODD becomes a precharge control signal.

Although the present invention has so far been described with reference to preferred examples, the present invention is not to be restricted to the examples. It is to be appreciated that those skilled in the art can change or modify the examples without departing from the scope and spirit of the invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor memory device comprising:
a memory cell array including a plurality of memory cells arranged in association with a plurality of word lines and bit lines; and
a switching control unit that exercises switching control of connection between a bit line pair of a sense amplifier and corresponding bit lines of said memory cell array; wherein
if a bit line of said memory cell array, connected to a memory cell selected by a word line, is a first bit line as seen from said sense amplifier, said switching control unit connects said first bit line to a first bit line of said bit line pair of said sense amplifier and connects a second bit line of said bit line pair of said sense amplifier to a bit line of said memory cell array connected to a non-selected memory cell; and wherein
if a bit line of said memory cell array, connected to a memory cell selected by a word line, is a second bit line as seen from said sense amplifier, said switching control unit connects said second bit line to said first bit line of said bit line pair of said sense amplifier and connects said second bit line of said bit line pair of said sense amplifier to a bit line of said memory cell array connected to a non-selected memory cell.

2. The semiconductor memory device according to claim 1, wherein
three bit lines, namely first to third bit lines, are allocated as bit lines of said memory cell array relating to the sense amplifier;
the first bit line and/or the third bit line of said three bit lines have switchable connection with a bit line pair of a sense amplifier neighboring to said sense amplifier or with bit line pairs of sense amplifiers on both sides of said sense amplifier; and
(2n+1) bit lines of said memory cell array are related with (n) of said sense amplifiers; n being a positive integer;
said switching control unit connecting, if the bit line of the memory cell array connected to the memory cell selected by said word line is said first bit line allocated to said bit line pair of said sense amplifier, said first bit line of said memory cell array to said first bit line constituting said bit line pair of said sense amplifier; said switching control unit also connecting said second bit line of said memory cell array to said second bit line constituting said bit line pair of said sense amplifier;
said switching control unit connecting, if the bit line of the memory cell array connected to the memory cell selected by said word line is said second bit line allocated to said bit line pair of said sense amplifier, said second bit line of said memory cell array to said first bit line constituting said bit line pair of said sense amplifier; said switching control unit also connecting said third bit line of said memory cell array to said second bit line constituting said bit line pair of said sense amplifier;
the bit line of said sense amplifier connected to the memory cell accessed is the first bit line for all time regardless of which of the word lines is selected.

3. The semiconductor memory device according to claim 2, wherein
said first bit line of said bit line pair of said sense amplifier is connected to a connection node of two transfer gates connected in series between the ends towards said sense amplifier of said first bit line and said second bit line of said memory cell array relating to said sense amplifier;
said second bit line of said bit line pair of said sense amplifier is connected to a connection node of two transfer gates connected in series between the ends towards said sense amplifier of said second bit line and said third bit line of said memory cell array relating to said sense amplifier; and wherein
even-numbered transfer gates or odd-numbered transfer gates of a transfer gate group are on/off controlled in common by a first control signal; said odd-numbered transfer gates or even-numbered transfer gates being on/off controlled in common by a second control signal.

4. A semiconductor memory device including:
a memory cell array comprising a plurality of memory cells arranged in association with a plurality of word lines and bit lines; and
a plurality of transfer gates, each of which on/off controls connection between a bit line pair of an associated sense amplifier and associated bit lines of a memory cell array; wherein
a first bit line of a bit line pair of said sense amplifier is connected to a connection node of two transfer gates connected in series between the ends towards said sense amplifier of said first bit line and said second bit line of said memory cell array relating to said sense amplifier;
a second bit line of said bit line pair of said sense amplifier is connected to a connection node of two transfer gates connected in series between the ends towards said sense amplifier of said second bit line and said third bit line of said memory cell array relating to said sense amplifier;
said first bit line and/or said third bit line having switchable connection with a bit line pair of a sense amplifier neighboring to said sense amplifier or with bit line pairs of sense amplifiers on both sides of said sense amplifier;
(2n+1) bit lines of said memory cell array being related with n of said sense amplifiers; n being a positive integer; and wherein
a set of said transfer gates provided between the ends towards said sense amplifier of the bit lines memory cell array includes first and second sorts of transfer gates;
the first sort of transfer gates being on/off controlled by a first control signal in common; the second sort of transfer gates being on/off controlled by a second control signal in common.

5. The semiconductor memory device according to claim 1, wherein said switching control unit exercises switching control between a connection configuration in which said first and second bit lines of said bit line pair of said sense amplifier are connected to even-numbered and odd-numbered bit lines of said memory cell array, relating to said sense amplifier, respectively; and
a connection configuration in which first and second bit lines of said bit line pair of said sense amplifier are connected to odd-numbered and even-numbered bit lines of said memory cell array relating to said sense amplifier, respectively; wherein
the bit line of said sense amplifier connected to the memory cell accessed is the first bit line for all time regardless of which of the word lines is selected.

6. The semiconductor memory device according to claim 5, wherein said first bit line of said bit line pair of said sense amplifier is connected to a connection node of two neighboring transfer gates between the ends of said first bit line and said second bit line of said memory cell array relating to said sense amplifier;
said second bit line of said bit line pair of said sense amplifier is connected to a connection node of two neighboring transfer gates between the ends of said second bit line and said third bit line of said memory cell array relating to said sense amplifier; and wherein
out of the transfer gates, connected between the ends of said neighboring bit lines of said memory cell array, even-numbered transfer gates are on/off controlled by a first control signal in common, and odd-numbered transfer gates are on/off controlled by a second control signal in common.

7. The semiconductor memory device according to claim 4, wherein
the transfer gates are all turned on by said first and second control signals to connect all of said bit lines to carry out the precharging/equalizing operation.

8. The semiconductor memory device according to claim 6, wherein
the transfer gates are all turned on by said first and second control signals to connect all of said bit lines to carry out the precharging/equalizing operation.

9. The semiconductor memory device according to claim 4, comprising precharging transistors, which are on/off controlled by said first and second control signals, and are connected to said precharging power supply potential and to one of bit lines of said bit line pair of said sense amplifier.

10. The semiconductor memory device according to claim 6, comprising precharging transistors, which are on/off controlled by said first and second control signals, and are connected to said precharging power supply potential and to one of bit lines of said bit line pair of said sense amplifier.

11. The semiconductor memory device according to claim 4, further comprising:
a logic circuit that generates a precharging control signal controlling precharging of said bit line pair of said sense amplifier based on the result of logical operation on said first and second control signals.

12. The semiconductor memory device according to claim 6, further comprising:
a logic circuit that generates a precharging control signal controlling precharging of said bit line pair of said sense amplifier based on the result of logical operation on said first and second control signals.

13. The semiconductor memory device according to claim 1, including, as said sense amplifier, a shared sense amplifier which is shared by memory cell arrays provided on both sides thereof.

14. The semiconductor memory device according to claim 4, wherein
bit lines of said sense amplifier and bit lines of said memory cell array are arranged alternately and in opposition to each other;
one ends of said bit lines of said sense amplifier towards said memory cell array are extended a preset length in the longitudinal direction beyond the other ends of said bit lines of said memory cell;
said first control signal is arranged as a gate electrode pattern intersecting the bit lines of said sense amplifier or the bit lines of said memory cell array;
said second control signal is arranged as a gate electrode pattern intersecting the bit lines of said memory cell array or the bit lines of said sense amplifier;
diffusion regions of the transfer gate are arranged on a surface of a semiconductor substrate on both oblique sides with respect to the longitudinal direction of each of the gate electrode patterns of said first and second control signals; and wherein
when one of the diffusion regions on both oblique sides of said gate electrode pattern is connected to the bit line of said sense amplifier, the other diffusion region is connected to the bit line of said memory cell array.

15. The semiconductor memory device according to claim 6, wherein
bit lines of said sense amplifier and bit lines of said memory cell array are arranged alternately and in opposition to each other;
one ends of said bit lines of said sense amplifier towards said memory cell array are extended a preset length in the longitudinal direction beyond the other ends of said bit lines of said memory cell;
said first control signal is arranged as a gate electrode pattern intersecting the bit lines of said sense amplifier or the bit lines of said memory cell array;
said second control signal is arranged as a gate electrode pattern intersecting the bit lines of said memory cell array or the bit lines of said sense amplifier;
diffusion regions of the transfer gate are arranged on a surface of a semiconductor substrate on both oblique sides with respect to the longitudinal direction of each of the gate electrode patterns of said first and second control signals; and wherein
when one of the diffusion regions on both oblique sides of said gate electrode pattern is connected to the bit line of said sense amplifier, the other diffusion region is connected to the bit line of said memory cell array.

16. A semiconductor device comprising the semiconductor memory device as set forth in claim 1, said semiconductor memory device including a memory cell array including first and second bit lines connected to first and second memory cells which are selected by first and second word lines, respectively; wherein
the relationship of correspondence in which the case where first and second bit lines of a bit line pair of a sense amplifier provided in association with said first and second memory cells are logic values 1 and 0, respectively, corresponds to a high potential of cell data of the selected memory cell, and the case where said first and second bit lines of said bit line pair of said sense amplifier are of logic values 0 and 1 corresponds to a low potential of cell data of the selected memory cell, is the same insofar as said first and second memory cells are concerned.

17. A semiconductor device comprising:
a first group of signal lines and a second group of signal lines arranged alternately, being spaced apart and in opposition to each other;
the end of said first group of signals being extended beyond the end of said second group of control signals a preset length in the longitudinal direction;
a first control signal arranged as a gate electrode pattern for intersecting said first group of signal lines;
a second control signal arranged as a gate electrode pattern for intersecting said first and second group of signal lines; and
diffusion regions of a transfer gate arranged on each of surface parts of a semiconductor substrate, said diffusion regions lying obliquely on both sides of the longitudinal direction of the gate electrode pattern of each of said first and second control signals;
said diffusion region lying obliquely on one side of said gate electrode patterns being connected to said first signal line, with the other diffusion region being connected to said second signal line; wherein
said first signal line is connected to said second signal line, neighboring to said first signal line on one side, when said first control signal is on; and wherein
said first signal line is connected to said second signal line, neighboring to said first signal line on the opposite side, when said second control signal is on.
